(19) United States
(12) Patent Application Publication
(10) Pub. No.: US 2025/0183571 A1
(43) Pub. Date: Jun. 5, 2025

(54) INTERPOSER MODULE FOR IMPLEMENTING DENSELY PITCHED INTEGRATED CIRCUITS ON CONVENTIONAL MOTHERBOARDS

(71) Applicant: BAE SYSTEMS Information and Electronic Systems Integration Inc., Nashua, NH (US)

(72) Inventors: Andrew M. Kraemer, Manchester, NH (US); Nicholas L. Campbell, Nashua, NH (US); Kevin S. Bassett, Nottingham, NH (US); Peter DiSalvo, Bedford, NH (US)

(73) Assignee: BAE SYSTEMS Information and Electronic Systems Integration Inc., Nashua, NH (US)

(21) Appl. No.: 18/524,300

(22) Filed: Nov. 30, 2023

(51) Int. Cl. H01R 12/71; H01L 23/00; H01L 23/498; H01R 12/75; H01R 43/26

(52) U.S. Cl. CPC H01R 12/716; H01L 23/49838; H01L 24/16; H01L 24/81; H01R 12/75; H01R 43/26; H01L 2224/16227; H01L 2224/81

(57) ABSTRACT

An interposer module incorporates at least one flip-chip or other densely pitched IC (DP-chip) into a motherboard assembly without placing undue requirements on the motherboard. The interposer module includes a rigid, densely pitched, multilayer circuit card having an interconnection array for attachment of the DP-chip interconnection points, and a mezzanine connector for removable mating to a compatible motherboard interconnector. Clusters of power connections, clusters of differential pairs of high frequency connections, and clusters of low frequency control connections and/or differential pairs of clock connections are each surrounded and isolated by ground connections. A compartment cover having a lid and isolating dividers can be placed over the DP-chip to isolate high frequency areas of the module from each other and from other RF sensitive areas. Thermally conductive material can extend from the cover lid to the DP-chip, and a cooling fan can circulate air past cooling fingers extending from the lid.

### RELATED APPLICATIONS

This application is related to U.S. patent application Ser. No. 18/524,667, filed concurrently with this application, which is herein incorporated by reference in its entirety for all purposes.

### FIELD

The disclosure relates to circuit assemblies, and more particularly, to motherboard circuit assemblies that include at least one densely pitched integrated circuit, such as a densely pitched flip-chip.

### BACKGROUND

For applications where it is important to minimize the size and weight of electronic systems, integrated circuits must be made as small as possible. This requires that the connection points on the integrated circuit be closely spaced together, i.e. “densely pitched.” Indeed, densely pitched integrated circuits with advanced packaging can measure 8 mm by 10 mm having approximately 1000 electrical interconnection points spaced apart by a pitch of less than 250 microns. As the equipment and technology improves, fine pitches well under 100 microns are being implemented. As used herein, the terms “densely pitched” (DP), “finely pitched” (FP) and “fine pitch” (FP) refer to a pitch of less than 250 microns.

Unfortunately, mounting a fine pitch chip directly to a motherboard can be problematic, in part because warping and other variances in the fabrication and assembly process can easily occur on large circuit cards, causing the connections to be unreliable, in part because the flexibility of the motherboard can cause the connections to fail even after they are established, and in part because it can be difficult to provide motherboard traces that are sufficiently narrow to establish contact with all of the closely pitched connections of a densely pitched chip. Furthermore, closely-spaced traces on the motherboard can lead to “crosstalk” interference between high frequency signals as they traverse the motherboard. This can require the implementation of specialized, shielded interconnections and connectors on the motherboard. These demanding motherboard requirements can greatly increase the cost of a circuit assembly.

What is needed, therefore, is an apparatus and method for incorporating an integrated circuit having a large number of closely spaced interconnection points into a motherboard circuit assembly without placing undue requirements on the motherboard, and while substantially eliminating crosstalk between traces.

### SUMMARY

Accordingly, one general aspect of the present disclosure is an interposer module that is suitable for interconnecting at least one densely pitched integrated circuit (“DP-chip”), such as a densely pitched flip-chip, with a motherboard. The interposer module includes an interposer circuit card having a DP-chip interconnection array on an upper surface thereof. The DP-chip interconnection array includes a plurality of DP-chip ground connection pads, at least one DP-chip power connection pad, and a plurality of DP-chip AC connection pads. At least one mezzanine connector extends from a lower surface of the interposer circuit card, where each of the mezzanine connectors includes a plurality of mezzanine connections. A plurality of interposer interconnections extend between the DP-chip interconnection array and the mezzanine connections.

The mezzanine connections include a plurality of mezzanine ground connections interconnected by the interposer interconnections with the plurality of DP-chip ground connection pads, at least one mezzanine power connection interconnected by the interposer interconnections with the at least one DP-chip power connection pad, and a plurality of mezzanine AC connections interconnected by the interposer interconnections with the plurality of DP-chip AC connection pads.

In embodiments, the mezzanine AC connections include a plurality of high frequency mezzanine connections configured to carry high frequency signals having frequencies above 50 MHz, and the mezzanine connections are configured such that all of the mezzanine power connections are arranged in power clusters, each power cluster including one or more of the mezzanine power connections arranged in a mutually adjacent configuration, each of the power clusters being completely surrounded by one or more of the mezzanine ground connections, and all of the mezzanine high frequency connections are arranged in high frequency clusters of high frequency differential pairs of the mezzanine high frequency connections, each of the high frequency differential pairs being configured to carry high frequency signals that are equal in magnitude, but opposite in polarity, each of the high frequency clusters being completely surrounded by one or more of the mezzanine ground connections.

In various embodiments, the mezzanine connections include at least one mezzanine clock connection configured to communicate clock signals having frequencies between 1 MHz and 50 MHz, and all of the mezzanine clock connections are arranged in differential pairs of mezzanine clock connections configured to carry clock signals that are equal in magnitude, but opposite in polarity. In some of these embodiments, the mezzanine connections include at least one mezzanine control connection configured to communicate signals having frequencies above zero Hz but below 1 MHz, and all of the mezzanine control connections are arranged in low frequency clusters, each low frequency cluster including either one or more of the mezzanine control connections arranged in a mutually adjacent configuration, one or more of the differential pairs of mezzanine clock connections arranged in a mutually adjacent configuration, or a combination thereof, each of the low frequency clusters being completely surrounded by one or more of the mezzanine ground connections.

Some embodiments further include a breakout connector extending from the upper surface of the interposer circuit card and a breakout interconnection configured for interconnecting the breakout connector with the DP-chip interconnection array, the breakout connector being configured for direct interconnection with an external device that is not mounted to the motherboard.

Another general aspect of the present disclosure is a method of using the disclosed interposer module to interconnect at least one densely pitched integrated circuit (“DP-chip”), such as a densely pitched flip-chip, with a motherboard.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1A is a perspective view from above of an interconnection array of a flip-chip of the prior art;

FIG. 1B is a side view of a flip-chip of the prior art;

FIG. 1C is a side view illustrating interconnection of a flip-chip die with the motherboard of a circuit assembly of the prior art;

FIG. 2A is aside view of an interposer module interconnected with an underlying motherboard in an embodiment of the present disclosure;

FIG. 2B is a perspective view from above, drawn to scale, of an interposer module in an embodiment of the present disclosure;

FIG. 2C is a perspective view from below, drawn to scale, of the interposer module of FIG. 2A;

FIG. 2D is a top view, drawn to scale, of the interposer module of FIG. 2A;

FIG. 2E is a bottom view, drawn to scale, of the interposer module of FIG. 2A;

FIG. 3 is a chart illustrating the arrangement of the mezzanine connections in the embodiment of FIG. 2A;

FIG. 4A is a perspective view from below, drawn to scale, of a compartment cover in an embodiment of the present disclosure;

FIG. 4B is an exploded perspective view from above, drawn to scale, of the compartment cover of FIG. 4A positioned over the interposer module of FIG. 2A and an underlying motherboard;

FIG. 4C is a perspective view, drawn to scale, of the compartment cover of FIG. 4A installed over the interposer module of FIG. 2A;

FIG. 5A is an exploded perspective view from above, drawn to scale, of a compartment cover having cooling fingers and a cooling fan positioned above the interposer module of FIG. 2A and an underlying motherboard;

FIG. 5B. is a perspective from above, drawn to scale, of the compartment cover with cooling fingers and fan of FIG. 5A installed over the interposer module of FIG. 2A; and

FIG. 6 is a flow diagram illustrating a method embodiment of the present disclosure.

### DETAILED DESCRIPTION

Embodiments of the present disclosure are directed to an apparatus and method for incorporating a densely pitched integrated circuit (“DP-chip”) into a motherboard circuit assembly, without placing undue requirements on the motherboard, and while substantially eliminating crosstalk between traces.

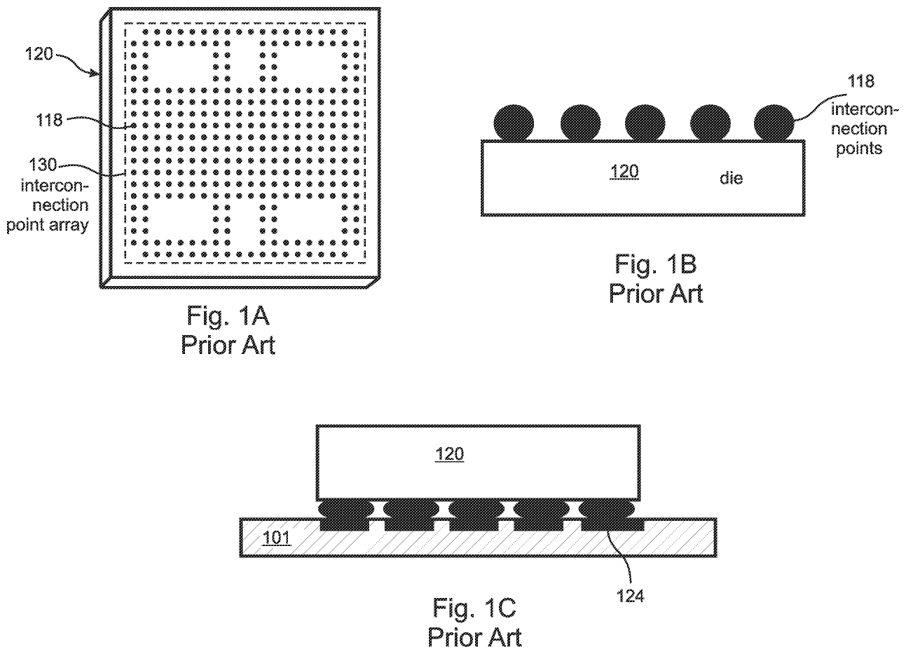

One approach to making integrated circuits as small as possible is to implement “chip-scale” packaging (CSP), where the package is no larger than the die itself. According to this approach, with reference to FIGS. 1A and 1B, very small “bumps” of solder are formed as interconnection points 118 on the tops of the dies 120 during the final wafer processing step, before the individual dies 120 are cut from the wafer. This is sometimes referred to as “wafer level packaging” or “WLP,” where the “packaging” refers here to the bumps that are applied as interconnection points 118 to the dies. The interconnection points 118 are not limited to only the periphery of the die 120, but can be provided as an interconnection point array 130 of a plurality of interconnection points 118 that takes advantage of most of the footprint of the die 120.

After the dies 120 are cut from the wafer, each of the dies 120 is “flipped” so that its interconnection points 118 are facing downward. With reference to FIG. 1C, the die 120 is then positioned so that its interconnection points 118 are aligned with a corresponding array of solder bump connection pads 124 provided on a motherboard 101. The solder bumps on the interconnection points 118 are then re-flowed by any of several known heating methods, such that all of the required interconnections to the motherboard 101 are formed simultaneously.

Devices of this type, i.e. dies 120 to which “bumps” have been applied as interconnection points 118, e.g. for wave soldering, are frequently referred to in the industry as “flip-chips.” The term “flip-chip” is also frequently used in the industry to refer to the WLP CSP manufacturing process, and/or to the method of attaching such devices to external circuitry (e.g. motherboards 101). However, it will be understood that the term “flip-chip” is used herein exclusively to refer to the device itself, and not to its method of manufacture, nor to the method of interconnecting the device with motherboards, or with other external circuitry.

In general, the interconnection points 118 of a flip-chip can include both “DC” and “AC” interconnection points, where the “DC” interconnection points include ground interconnection points as well as other fixed voltage interconnection points that remain substantially constant in voltage, referred to herein generically as “power” interconnection points. The “AC” interconnection points carry either analog or digital signals that vary in voltage with time according to a sinusoidal frequency (analog) or chip rate (digital), where both are referred to generically herein as the “frequency” of the signals. As used herein, the “AC” signals include RF signals as well as AC power or control signals. The AC interconnection points can be characterized according to their frequency range, with “low frequency” interconnection points being configured to carry “low frequency” signals, referred to generically herein as “control” signals, having frequencies below 1 MHZ, “mid-frequency” interconnection points being configured to carry “mid-frequency” signals, referred to generically herein as “clock” signals, having frequencies from 1 MHz to 50 MHz, and “high-frequency” interconnection points being configured to carry “high frequency” signals having frequencies above 50 MHz. Note that, according to these definitions, an AC voltage that oscillates, for example at 50 Hz or 60 Hz, falls into the “control signal” category, even though it may be intended to provide power to the flip-chip. The locations of the power, signal, and ground interconnection points are arranged to provide optimal signal integrity and performance.

Exemplary embodiments of the present disclosure are described herein with reference to a densely pitched “flip-chip.” However, it will be understood that the scope of the present disclosure extends to incorporating any unpackaged integrated circuit into a motherboard circuit assembly. Accordingly, references herein to a “flip-chip” will be understood to refer to any unpackaged integrated circuit, unless otherwise stated or required by context.

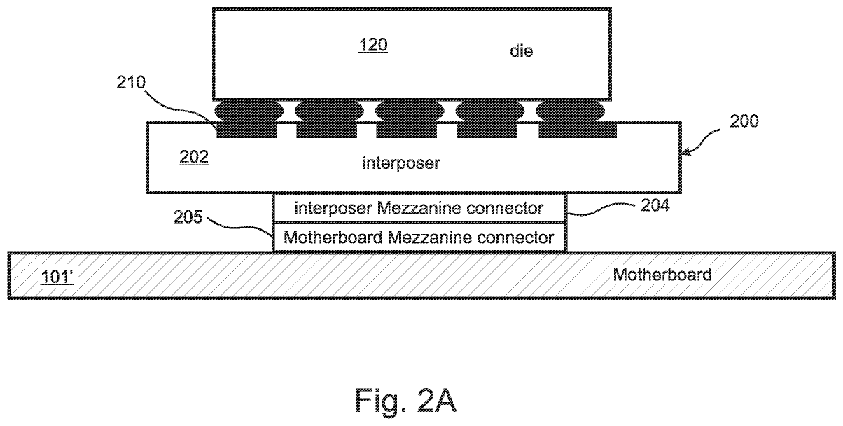

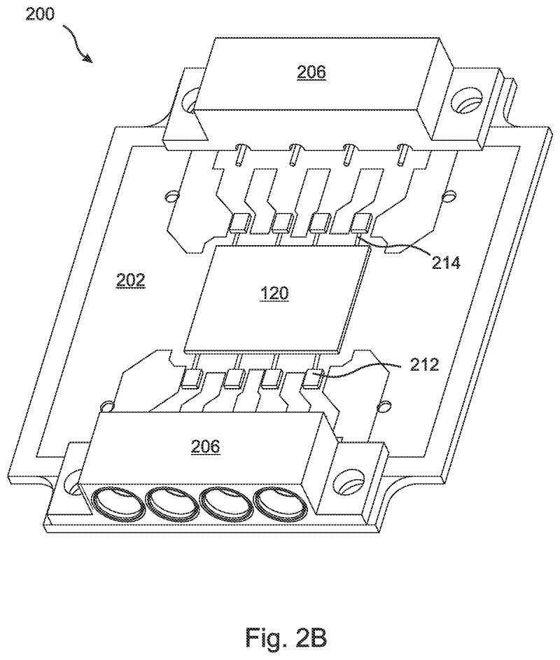

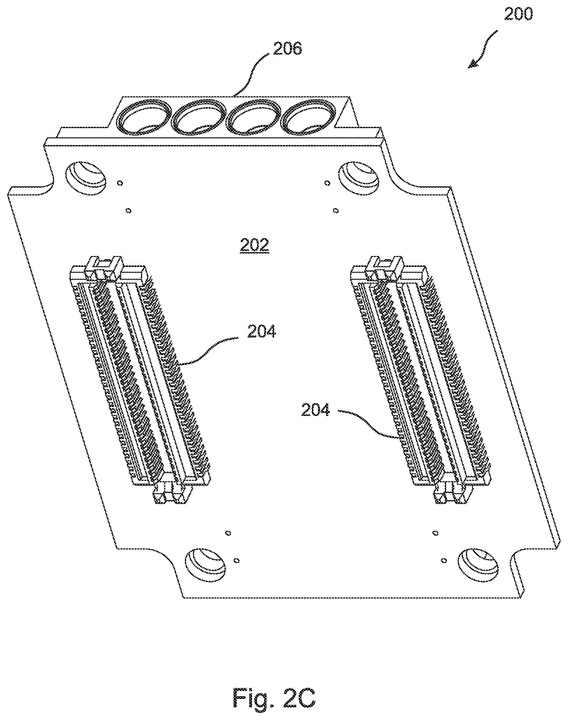

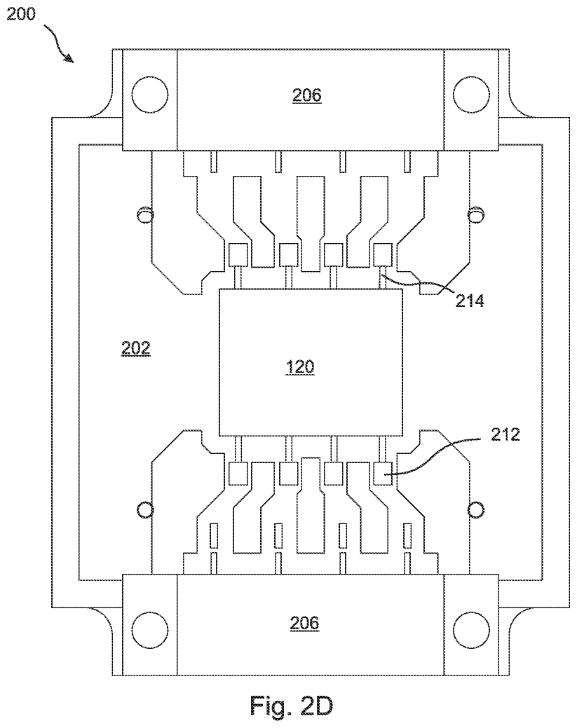

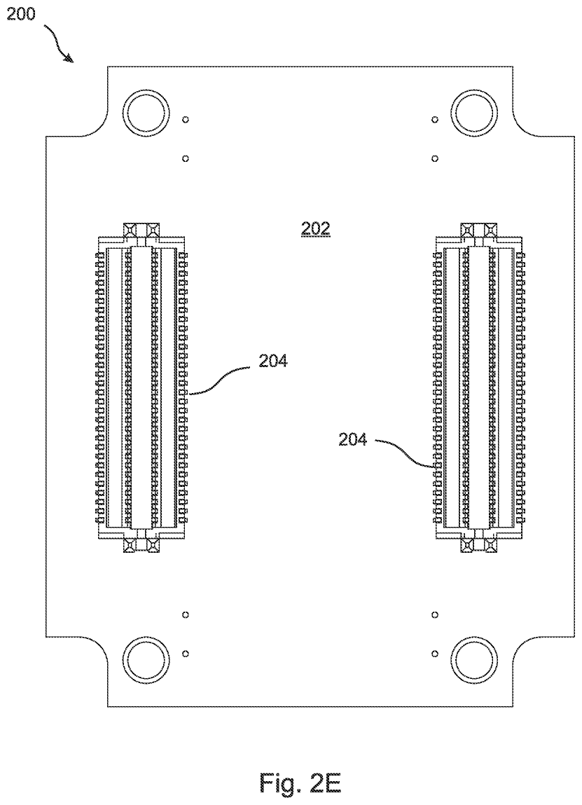

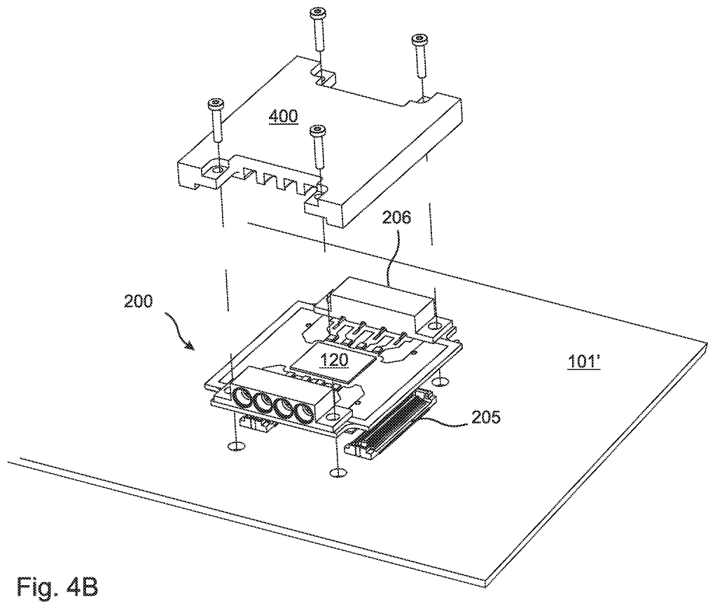

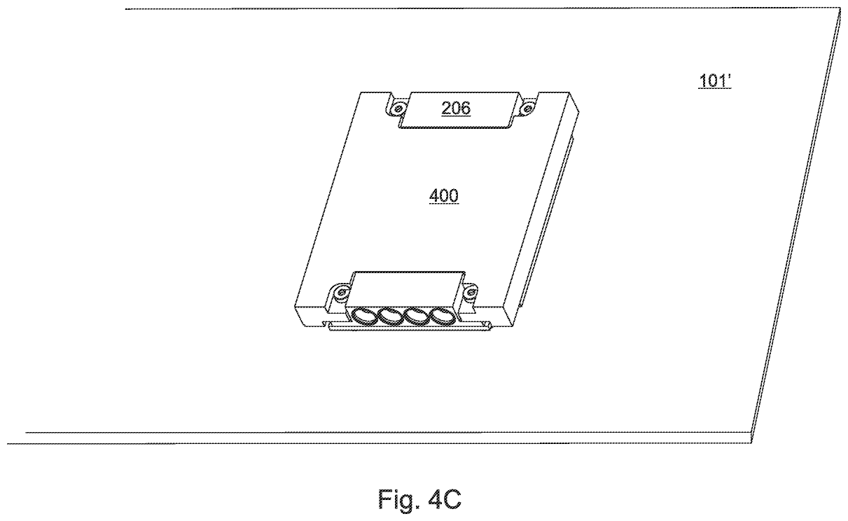

With respect to FIGS. 2A-2E, the disclosed apparatus is referred to herein as an “interposer module” 200. FIG. 2A is a side view showing an embodiment of the interposer module 200 installed on a motherboard. FIGS. 2B and 2C are perspective views, respectively, of an exemplary embodiment of the interposer module 200 shown from above and from below, while FIGS. 2D and 2E are top and bottom views, respectively, of the exemplary embodiment. In the exemplary embodiment, the interposer module 200 includes a relatively small, densely pitched, high rigidity, multi-layer interposer circuit card 202 that comprises an array of solder bump connection pads 210 on its upper surface, to which a flip-chip or other densely pitched integrated circuit die 120 can be mounted, as shown in FIGS. 2A, 2B and 2D. The interposer module 200 further includes and at least one interposer mezzanine connector 204 on its lower surface that is configured for removable attachment to a compatible connector or connectors, referred to herein as “motherboard interconnectors” 205, provided on an otherwise conventional motherboard 101′ (See FIG. 4B). In one example the motherboard 101′ has corresponding motherboard mezzanine connectors 205 that mate with the interposer mezzanine connectors 204. The embodiment of FIGS. 2A-2E includes two Samtec® ADM6/ADF6™ 120 pin interposer mezzanine connectors 204. Similar embodiments include Samtec® HTS™ or Q-Strip™ connectors. (Samtec® is a registered trademark of Samtec Inc.).

The disclosed interposer module 200 is inherently less prone to warping and other variances in the fabrication and assembly process as compared to a conventional motherboard, due to its smaller size, higher rigidity, and more demanding production specifications as compared to a conventional motherboard. The interposer mezzanine connectors 204 mated with the motherboard connectors 205 provide robust connectivity that can withstand flexing when the interposer module 200 is mounted on the motherboard 101′. Also, the distribution by the mezzanine connectors 204 of the DP-chip signals over a wider area allows the motherboard 101′ to be conventional in pitch, and eliminates any need, in many cases, for the motherboard 101′ to include interior printed circuit layers. In the embodiment illustrated in FIGS. 2A-2E, the interposer circuit card 202 is an 8-layer circuit card. In similar embodiments, the interposer circuit card 202 includes between 4 layers and 12 layers or more. The multilayer interposer circuit card 202 employs signal traces and vias to route the signals between the interconnection array 210 of the interposer module 200 to the interposer mezzanine connectors 204.

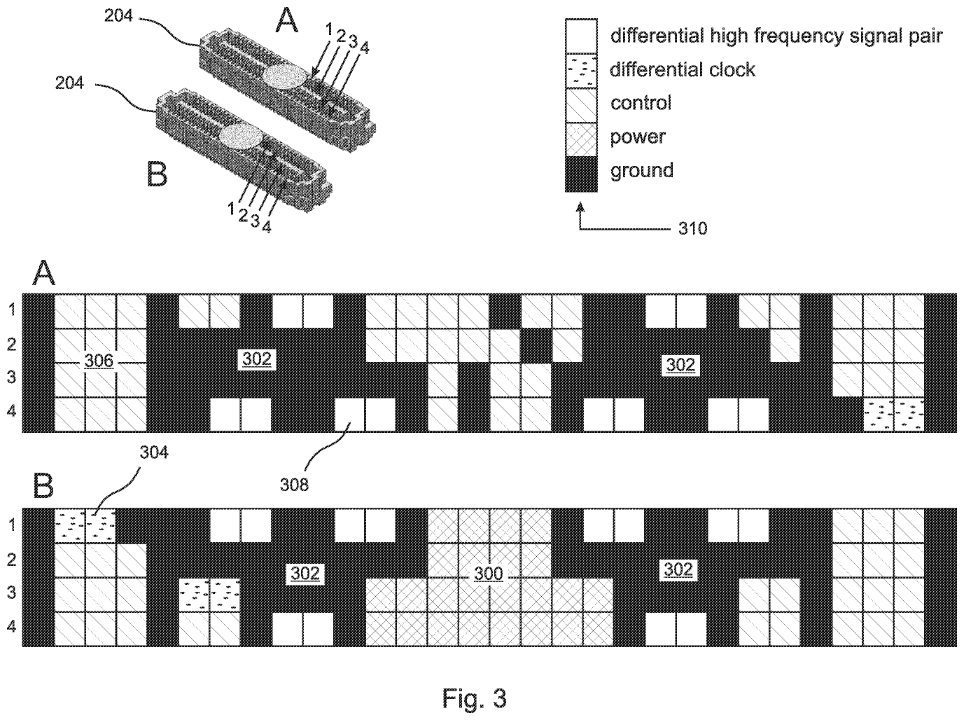

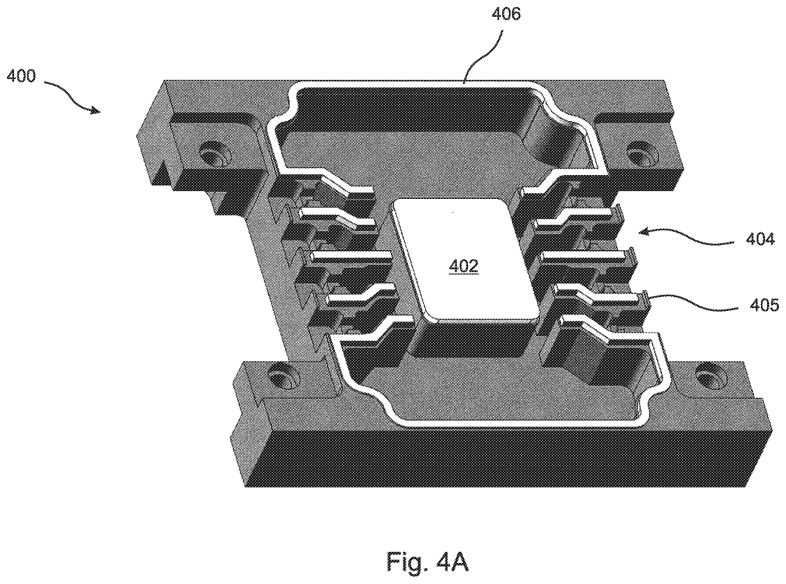

With reference to FIG. 3, signal interference between the individual interposer mezzanine connections 310 included in the interposer mezzanine connectors 204 (individual small squares in FIG. 3), and between the traces that interconnect the interconnection array 210 of the interposer module 200 with the interposer mezzanine connectors 204, is minimized by assigning signals from the die 120 through the interposer circuit card 202 to the interposer mezzanine connections 310 and associated traces according to the following rules:
a. all of the interposer mezzanine power connections and power traces are grouped together in a single power cluster 300, which is entirely surrounded by mezzanine ground connections 302 and ground traces that isolate the power cluster 300 and prevent AC signals from cross-contaminating the DC power lines and being thereby distributed throughout the motherboard, as well as preventing any “noise” that may be on the power lines from cross-contaminating the AC signals;
b. all of the clock mezzanine connections and clock traces are arranged in differential pairs of conductors 304 that are configured to carry signals which are equal in magnitude, but opposite in polarity;
c. all of the mezzanine control connections and control traces are grouped in low frequency clusters 306 that only contain control signals, and possibly also clock differential pairs 304, each of the low frequency clusters 306 being entirely surrounded and isolated by mezzanine ground connections 302 and ground traces; and
d. all of the mezzanine high frequency signal connections and high frequency traces are arranged in high frequency clusters of physically isolated differential pairs 308 that are surrounded by mezzanine ground connections 302 and ground traces.

With reference again to FIGS. 2B through 2D, in embodiments the interposer module 200 further includes one or more interposer “breakout” connectors 206 that are coupled through the interposer circuit card 202 by signal traces 214 and/or vias to the connection pads of the DP-chip interconnection array 210. In the illustrated embodiment, the breakout connectors 206 are high frequency GPPO® connectors. (GPPO® is a registered trademark of Corning Gilbert Inc.). Specifically, the breakout connectors 206 in the illustrated embodiment include a total of eight breakout connections consisting of two adjacent pairs that provide signal input and output, respectively, from 100 MHz to 10 GHz, and two adjacent pairs that provide signal input and output, respectively, from 4 GHz to 40 GHz. The breakout connectors 206 further alleviate any need to provide specialized high frequency signal lines or other specialized signal features on the motherboard 101′. Embodiments further include passive components that support the signal routing of the interposer module 200, such as the baluns 212 in the illustrated embodiment that interconvert between individual signal lines and differential pairs of signal lines. Similar embodiments further include temperature sensors, voltage sensors, filter capacitors, and/or other supporting components on the interposer module 200.

With reference to FIGS. 4A-4C, various embodiments further include a a “compartment cover” 400 comprising a conductive lid, referred to herein as the “compartment cover lid,” that extends over the DP-chip 120, from which extend conductive, isolating dividers that are configured to isolate adjacent high frequency regions of the interposer module from each other, and from other RF-sensitive areas. In embodiments, the compartment cover 400 provides RF shielding and/or cooling to the DP-chip 120. In the illustrated embodiment, the interposer circuit card 202 itself serves as the “fourth wall” of a shielding compartment 400. In particular, a ground plane included in the interposer circuit card 202 forms an electrical connection with an RF gasket 406 of the compartment cover 400 and serves as the fourth “wall” of the RF shielding enclosure provided by the compartment cover 400. With reference to FIG. 4A, in the illustrated embodiment the compartment cover 400 further includes channels 404 formed by isolating dividers 405 that provide RF isolation between the traces or coaxial cables that conduct signals between the DP-chip 120 and the breakout connectors 206. In the illustrated embodiment, the compartment cover 400 also includes a thermal interface material (TIM) 402 that is in direct thermal contact with the DP-chip 120, causing the compartment cover 400 to function as a heat sink for the DP-chip 120.

FIG. 4A is a perspective view from below of a compartment cover 400 in an embodiment of the present disclosure. FIG. 4B is an exploded perspective view showing the interposer module 200 positioned above motherboard interconnectors 205 that are compatible with the mezzanine connectors 204 of the interposer module 200, and further shows the compartment cover 400 positioned above the interposer module 200. FIG. 4C is a perspective view showing the compartment cover 400 installed over the interposer module 200.

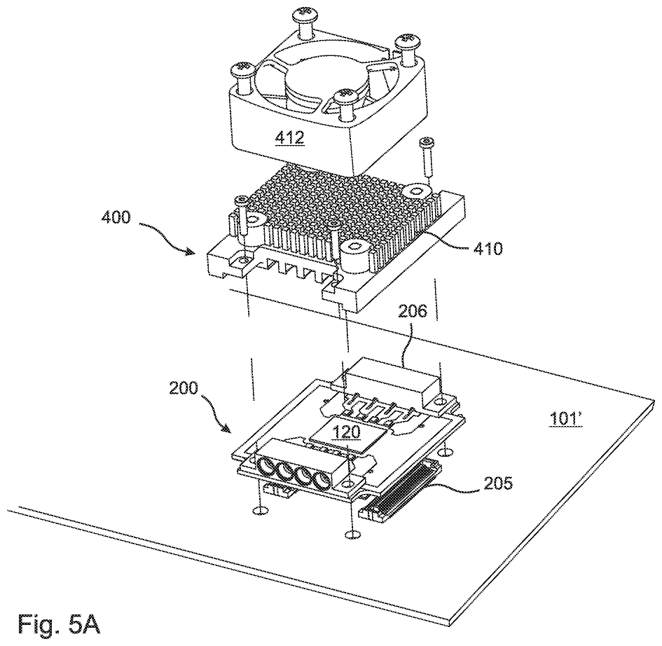

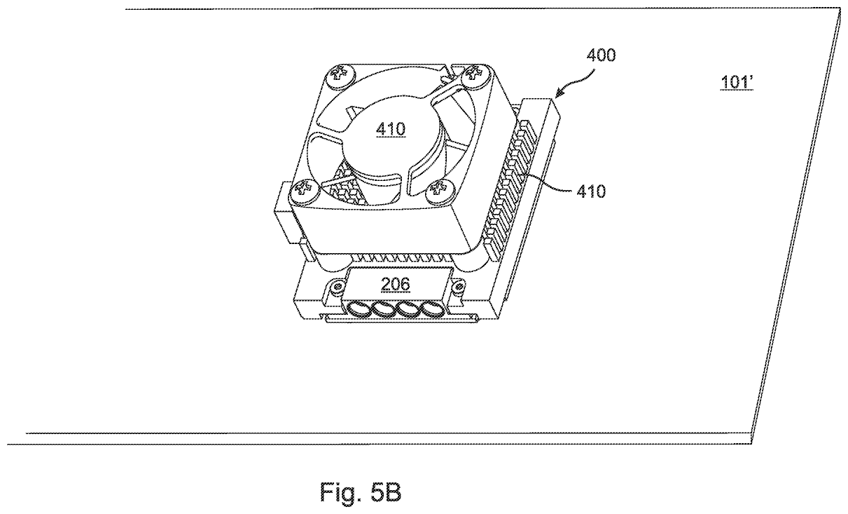

With respect to FIGS. 5A and 5B, embodiments further include cooling fingers 410 extending from the compartment cover lid, and a fan 412 mounted on top of the compartment cover lid to circulate air through the cooling fingers 410 and thereby actively cool the DP-chip 120. FIG. 5A is an exploded perspective view of the illustrated embodiment, and FIG. 5B is a perspective view of the assembled embodiment.

In summary, the disclosed interposer module 200 meets the requirements of a densely pitched integrated circuit, such as a flip-chip, including enhanced rigidity, dense pitch, and high frequency connectivity, and also, in embodiments, multiple layers and small diameter vias, thereby allowing the motherboard itself 101′ to be of conventional design. In addition, the use of mezzanine connectors 204 enables the motherboard 101′ or the interposer module 200 to be separately replaced if one or the other fails. Also, embodiments of the disclosed interposer module 200 can be ideal for evaluating new circuit assembly designs, by allowing the performance of the DP-chip 120 to be evaluated using various test motherboards 101′, and by allowing various new motherboard designs to be tested using the same interposer module 200.

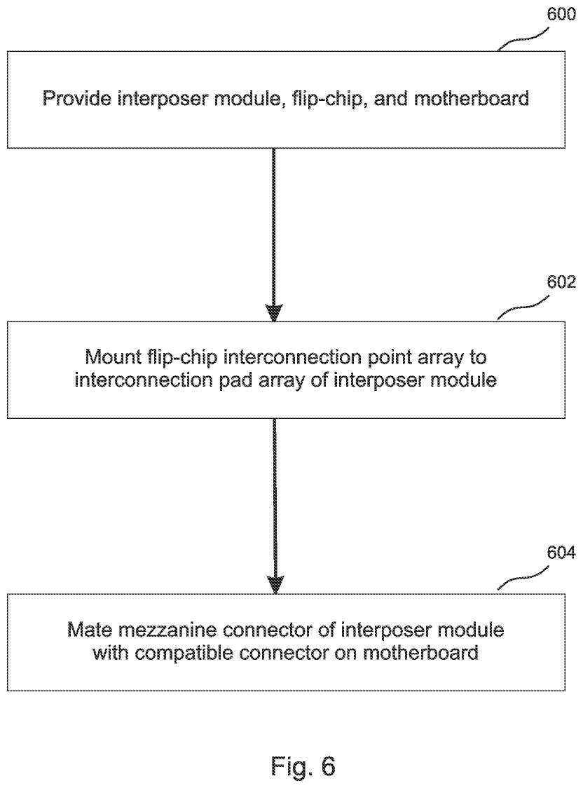

With reference to FIG. 6, in embodiments that are applicable to a flip-chip, the method of the present disclosure includes providing 600 an interposer module 200 as described above, as well as a flip-chip 120 and a motherboard 101′ having a motherboard interconnector 205 that is compatible with the mezzanine connector 204 of the interposer module 200. The interconnection point array 130 of the flip-chip 120 is then placed upon and aligned with the interconnection array 210 of the interposer module 200, and the solder bumps on the interconnection points 118 are melted so as to attach 602 the flip-chip 120 to the connection pads of the interconnection array 210 of the interposer module 200. Finally, the mezzanine connector 204 of the interposer module 200 is mated 604 with the motherboard interconnector 205 of the motherboard 101′.

For simplicity and clarity of illustration, the drawings and description presented herein are directed mainly to embodiments wherein only one densely pitched (DP) chip is attached to the disclosed interposer module. However, it will be understood that the scope of the present disclosure further includes embodiments wherein a plurality of DP-chips are attached to a single interposer module, as well as to embodiments in which a plurality of interposer modules are attached to the same motherboard, and to any combination thereof.

The foregoing description of the embodiments of the disclosure has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the disclosure to the precise form disclosed. Many modifications and variations are possible in light of this disclosure.

Although the present application is shown in a limited number of forms, the scope of the disclosure is not limited to just these forms, but is amenable to various changes and modifications. The present application does not explicitly recite all possible combinations of features that fall within the scope of the disclosure. The features disclosed herein for the various embodiments can generally be interchanged and combined into any combinations that are not self-contradictory without departing from the scope of the disclosure. In particular, the limitations presented in dependent claims below can be combined with their corresponding independent claims in any number and in any order without departing from the scope of this disclosure, unless the dependent claims are logically incompatible with each other.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of technology disclosed herein may be implemented using hardware, software, or a combination thereof. When implemented in software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone may be utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments. As such, one aspect or embodiment of the present disclosure may be a computer program product including least one non-transitory computer readable storage medium in operative communication with a processor, the storage medium having instructions stored thereon that, when executed by the processor, implement a method or process described herein, wherein the instructions comprise the steps to perform the method(s) or process(es) detailed herein.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software, and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. An interposer module suitable for interconnecting a densely pitched integrated circuit with a motherboard, the interposer module comprising:
an interposer circuit card having an interconnection array on an upper surface thereof, the interconnection array being configured for interconnection with the integrated circuit, the interconnection array comprising a plurality of ground connection pads, at least one power connection pad, and a plurality of AC connection pads;
at least one interposer mezzanine connector extending from a lower surface of the interposer circuit card, each of the at least one interposer mezzanine connector comprising a plurality of mezzanine connections; and
a plurality of interposer interconnections between the interconnection array and the mezzanine connections;
the mezzanine connections including a plurality of mezzanine ground connections interconnected by the interposer interconnections with the plurality of ground connection pads, at least one mezzanine power connection interconnected by the interposer interconnections with the at least one power connection pad, and a plurality of mezzanine AC connections interconnected by the interposer interconnections with the plurality of AC connection pads.

2. The interposer module of claim 1, wherein the mezzanine AC connections include a plurality of high frequency mezzanine connections configured to carry high frequency signals having frequencies above 50 MHz, and wherein the mezzanine connections are configured such that:
all of the mezzanine power connections are arranged in power clusters, each power cluster including one or more of the mezzanine power connections arranged in a mutually adjacent configuration, each of the power clusters being completely surrounded by one or more of the mezzanine ground connections; and
all of the mezzanine high frequency connections are arranged in high frequency clusters of high frequency differential pairs of the mezzanine high frequency connections, each of the high frequency differential pairs being configured to carry high frequency signals that are equal in magnitude, but opposite in polarity, each of the high frequency clusters being completely surrounded by one or more of the mezzanine ground connections.

3. The interposer module of claim 1, wherein:
the mezzanine connections include at least one mezzanine clock connection configured to communicate clock signals having frequencies between 1 MHz and 50 MHz; and
all of the mezzanine clock connections are arranged in differential pairs of mezzanine clock connections configured to carry clock signals that are equal in magnitude, but opposite in polarity.

4. The interposer module of claim 3, wherein:
the mezzanine connections include at least one mezzanine control connection configured to communicate signals having frequencies above zero Hz but below 1 MHz; and
all of the mezzanine control connections are arranged in low frequency clusters, each low frequency cluster including either one or more of the mezzanine control connections arranged in a mutually adjacent configuration, one or more of the differential pairs of mezzanine clock connections arranged in a mutually adjacent configuration, or a combination thereof, each of the low frequency clusters being completely surrounded by one or more of the mezzanine ground connections.

5. The interposer module of claim 1, further comprising a breakout connector extending from the upper surface of the interposer circuit card and a breakout interconnection configured for interconnecting the breakout connector with the interconnection array, the breakout connector being configured for direct interconnection with an external device.

6. The interposer module of claim 5, wherein the breakout connector is configured for exchanging signals having frequencies of up to 10 GHz with the external device.

7. The interposer module of claim 5, wherein the breakout connector is configured for exchanging signals having frequencies of up to 40 GHz with the external device.

8. The interposer module of claim 1, further comprising a compartment cover configured for installation over the integrated circuit, the compartment cover comprising an electrically conductive compartment cover lid and at least one electrically conductive isolating divider, wherein when the compartment cover is installed over the integrated circuit, the isolating dividers extend from the compartment cover lid to the interposer circuit card, thereby providing RF isolation between adjacent regions of the multilayer circuit card.

9. The interposer module of claim 8, wherein the compartment cover is configured, when installed over the integrated circuit, to make grounding interconnection with a ground plane of the interposer circuit card, thereby providing an RF-shielded enclosure about the integrated circuit.

10. The interposer module of claim 8, wherein the compartment cover further comprises thermal interface material that extends from the compartment cover lid into direct thermal contact with the integrated circuit.

11. The interposer module of claim 8, wherein the compartment further comprises a cooling fan configured to actively circulate air through cooling fingers provided on the compartment cover lid.

12. The interposer module of claim 1, wherein the interposer circuit card is a multilayer circuit card.

13. A method of interconnecting a densely pitched integrated circuit with a motherboard, the method comprising:
providing an interposer module according to claim 1;
providing an integrated circuit having an array of interconnection points that include a plurality of ground interconnection points, at least one power interconnection point, and at least one high frequency interconnection point configured to communicate signals having frequencies above 50 MHz;
providing a motherboard having a motherboard interconnector compatible for mating with the interposer mezzanine connector of the interposer module;
mounting the array of interconnection points of the integrated circuit to the interconnection array of the interposer module; and
mating the interposer mezzanine connector of the interposer module with the motherboard interconnector.

14. The method of claim 13, wherein the mezzanine AC connections of the interposer module include a plurality of high frequency mezzanine connections configured to carry high frequency signals having frequencies above 50 MHz, and wherein the mezzanine connections of the interposer module are configured such that:
all of the mezzanine power connections are arranged in power clusters, each power cluster including one or more of the mezzanine power connections arranged in a mutually adjacent configuration, each of the power clusters being completely surrounded by one or more of the mezzanine ground connections; and
all of the mezzanine high frequency connections are arranged in high frequency clusters of high frequency differential pairs of the mezzanine high frequency connections, each of the high frequency differential pairs being configured to carry high frequency signals that are equal in magnitude, but opposite in polarity, each of the high frequency clusters being completely surrounded by one or more of the mezzanine ground connections.

15. The method of claim 13, wherein the interposer module further comprises a breakout connector extending from the upper surface of the multilayer circuit card and a breakout interconnection configured for interconnecting the breakout connector with a high frequency connection pad of the interconnection array, and the method further includes directly interconnecting the breakout connector with an external device.

16. The method of claim 15, wherein the breakout connector is configured for exchanging signals having frequencies of up to 10 GHz with the external device.

17. The method of claim 15, wherein the breakout connector is configured for exchanging signals having frequencies of up to 40 GHz with the external device.

18. A flip-chip module, comprising:
a motherboard having one or more motherboard mezzanine connectors;
at least one interposer module, wherein each interposer module comprises;
an interposer circuit card having an interconnection array on a top surface thereof, the interconnection array being configured for interconnection with an integrated circuit, the interconnection array comprising a plurality of ground connection pads, at least one power connection pad, and a plurality of AC connection pads;
one or more interposer mezzanine connectors extending from a bottom surface of the interposer circuit card, the interposer mezzanine connectors comprising a plurality of mezzanine connections; and
a plurality of interposer interconnections between the interconnection array and the interposer mezzanine connections, wherein the interposer mezzanine connections include a plurality of interposer mezzanine ground connections interconnected by the interposer interconnections with the plurality of ground connection pads, at least one interposer mezzanine power connection interconnected by the interposer interconnections with the at least one power connection pad, and a plurality of interposer mezzanine AC connections interconnected by the interposer interconnections with the plurality of AC connection pads; and
for each of the interposer modules, at least one integrated circuit coupled to the interconnection array on the top surface of the interposer module,
wherein the one or more interposer mezzanine connectors are configured to couple with the one or more motherboard mezzanine connector.

19. The flip-chip module of claim 18, wherein the mezzanine AC connections include a plurality of high frequency mezzanine connections configured to carry high frequency signals having frequencies above 50 MHz, and wherein the mezzanine connections are configured such that:
all of the mezzanine power connections are arranged in power clusters, each power cluster including one or more of the mezzanine power connections arranged in a mutually adjacent configuration, each of the power clusters being completely surrounded by one or more of the mezzanine ground connections; and
all of the mezzanine high frequency connections are arranged in high frequency clusters of high frequency differential pairs of the mezzanine high frequency connections, each of the high frequency differential pairs being configured to carry high frequency signals that are equal in magnitude, but opposite in polarity, each of the high frequency clusters being completely surrounded by one or more of the mezzanine ground connections.

20. The flip-chip module of claim 18, further comprising a breakout connector extending from the upper surface of the interposer circuit card and a breakout interconnection configured for interconnecting the breakout connector with the interconnection array, the breakout connector being configured for direct interconnection with an external device.
